(19) United States
(12) Patent Application Publication
(10) Pub. No.: US 2023/0012572 A1
(43) Pub. Date: Jan. 19, 2023

(54) CIRCUIT BOARD ENHANCING STRUCTURE AND MANUFACTURE METHOD THEREOF

(71) Applicant: UNIMICRON TECHNOLOGY CORP., Taoyuan City (TW)

(72) Inventor: Tse-Wei Wang, Hsinchu City (TW)

(21) Appl. No.: 17/384,903

(22) Filed: Jul. 26, 2021

(30) Foreign Application Priority Data
Jul. 16, 2021 (TW) 110126309

(51) Int. Cl. H05K 1/11; H05K 3/00; H05K 3/46; H05K 3/42

(52) U.S. Cl. CPC H05K 1/115; H05K 3/0023; H05K 3/4644; H05K 3/429

(57) ABSTRACT

The invention discloses a circuit board enhancing structure and a manufacture method thereof. The method includes the following steps: providing a substrate; forming a first circuit on the substrate; forming a first dielectric layer enclosing the first circuit on the substrate; forming a first opening on the first dielectric layer; forming a first pattern photoresist layer on the first dielectric layer to divide a surface of the first dielectric layer as a first structure enhancing area and a second circuit area, wherein the first opening is disposed in the first structure enhancing area; forming a second circuit in the second circuit area and a first enhancing structure in the first opening, wherein the first enhancing structure protrudes from the first opening; removing the first pattern photoresist layer; and forming a second dielectric layer enclosing the second circuit and the first enhancing structure on the first dielectric layer.

### BACKGROUND OF THE INVENTION

### 1. Field of the Invention

The disclosure relates to an enhancing structure and a manufacture method thereof, and more particularly, a circuit board enhancing structure and a manufacture method thereof.

### 2. Description of the Related Art

Refer to FIG. 5A. FIG. 5A is a cross sectional view of a conventional circuit board structure 3. The conventional circuit board structure 3 includes a substrate 31, a first circuit 32, a first dielectric layer 33, a second circuit 34, a second dielectric layer 35, a third circuit 36 and a protective layer 37. The first circuit 32 is disposed on the substrate 31. The first dielectric layer 33 is disposed on the substrate 31 and encapsulates the first circuit 32. The surface of the first dielectric layer 33 has a first through hole 331. The second circuit 34 is disposed on the first dielectric layer 33. The second dielectric layer 35 is disposed on the first dielectric layer 33 and encapsulates the second circuit 34. The surface of the second dielectric layer 35 has a second through hole 351. The third circuit 36 is disposed on the second dielectric layer 35. The protective layer 37 is disposed on the second dielectric layer 35, exposes one part of the third circuit 36, and encapsulates the other part of the third circuit 36.

As mentioned above, when the first circuit 32 and the second circuit 34 are formed on the aforementioned circuit board structure 3, the first dielectric layer 33 and the second dielectric layer 35 respectively encapsulate the first circuit 32 and the second circuit 34 and are stacked on the substrate 31. However, if the circuit board structure 3 utilizes the first dielectric layer 33 and the second dielectric layer 35 that are made of the same or heterogeneous material to stack on the substrate 31, the bonding strength of the contact surface between the first dielectric layer 33 and the second dielectric layer 35 is weak. The second circuit 34 and the third circuit 36 fail to be compactly formed on the surfaces of the first dielectric layer 33 and the second dielectric layer 35.

Refer to FIG. 5. FIG. 5B is a partial enlargement view of the circuit board structure of FIG. 5A. After the first circuit 32 and the second circuit 34 are respectively formed on the first dielectric layer 33 and the second dielectric layer 35, the incomplete circuit board structure 3 is exposed in the air for a long time while waiting for the next testing process and forming process. In this environment, the incomplete circuit board structure 3 could absorb the moisture in the air so that the contact surface of the different layers in the incomplete circuit board structure 3 may be disengaged because of the popcorn effect in the next assembly process and the thermal process of the encapsulation. Particularly, the contact surfaces G1, G3 of the two adjacent dielectric layer, and the contact surfaces G2, G4 of the circuit and the dielectric layer both are easily disengaged because of the popcorn effect.

Moreover, in the process of forming the dielectric layer, the thermal stress is generated in the dielectric layer so that each region in the dielectric layer has a various difference value for the thermal stress after the dielectric layer has been roasted in the high temperature process and cured for a while—the theory of thermal expansion and cold shrinkage.

Accordingly, how to provide a circuit board enhancing structure and a manufacture method thereof to solve the problems mentioned above is an urgent subject to tackle.

### SUMMARY OF THE INVENTION

In view of this, the present invention provides a manufacture method of a circuit board enhancing structure, including the following steps: providing a substrate; forming a first circuit on the substrate; forming a first dielectric layer on the substrate and encapsulating the first circuit; forming at least one first opening on the surface of the first dielectric layer; according to a position of the at least one first opening on the surface of the first dielectric layer and a predetermined position of the second circuit on the surface of the first dielectric layer, forming the first pattern photoresist layer on the surface of the first dielectric layer to divide the surface of the first dielectric layer as the first structure enhancement region and the second circuit region by the first pattern photoresist layer, wherein the at least one first opening is disposed in the first structure enhancement region; forming the second circuit in the second circuit region and forming the first enhancing structure element in the first opening of the first structure enhancement region, wherein the first enhancing structure element protrudes from the first opening; removing the first pattern photoresist layer; forming the second dielectric layer on the first dielectric layer, encapsulating the second circuit and the first enhancing structure element; forming the at least one second opening on the surface of the second dielectric layer; according to the position of the at least one second opening on the surface of the second dielectric layer and the predetermined position of the third circuit on the surface of the second dielectric layer, forming the second pattern photoresist layer on the surface of the second dielectric layer to divide the surface of the second dielectric layer as the second structure enhancement region and the third circuit region by the second pattern photoresist layer, wherein at least one second opening is disposed in the second structure enhancement region; forming the third circuit in the third circuit region and forming the at least one second enhancing structure element in the at least one second opening of the second structure enhancement region, wherein the second enhancing structure element protrudes from at least one second opening; removing the second pattern photoresist layer; forming the protective layer on the second dielectric layer, encapsulating the second enhancing structure element and the third circuit; forming the at least one opening on the protective layer to expose a part of the third circuit.

As mentioned above, the circuit board enhancing structure and the manufacture method thereof of the present invention utilize the enhancing structure elements to enhance the vertical bonding strength of the contact surface between the various processes. For instance, the invention enhances the bonding strength between the various dielectric layers and enhances the bonding strength between the dielectric layer and the protective layer to overcome the problems of the prior art. In addition, the enhancing structure elements are inserted to the interior of the dielectric layer to decrease and release the thermal stress in the dielectric layer, to reinforce the strength of the whole structure of the circuit board and to improve the homogeneity of the electroplating process. In this way, the circuit board enhancing structure and the manufacture method thereof of the present invention can further be applied to the layered structure with a low thermal expansion coefficient and the structure of the 5G product with a low roughness surface.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1A to FIG. 1N are one schematic flowchart of the manufacture method of a circuit board enhancing structure of the present invention;

FIG. 2A to FIG. 2N are another schematic flowchart of the manufacture method of a circuit board enhancing structure of the present invention;

FIG. 3 is the cross sectional view of the circuit board enhancing structure manufactured by the manufacture method of a circuit board enhancing structure according to FIG. 1A to FIG. 1N;

FIG. 4 is the cross sectional view of the circuit board enhancing structure manufactured by the manufacture method of a circuit board enhancing structure according to FIG. 2A to FIG. 2N;

FIG. 5A is a cross sectional view of a conventional circuit board structure; and

FIG. 5B is a partial enlargement view of the circuit board structure of FIG. 5A.

### DETAILED DESCRIPTION OF THE INVENTION

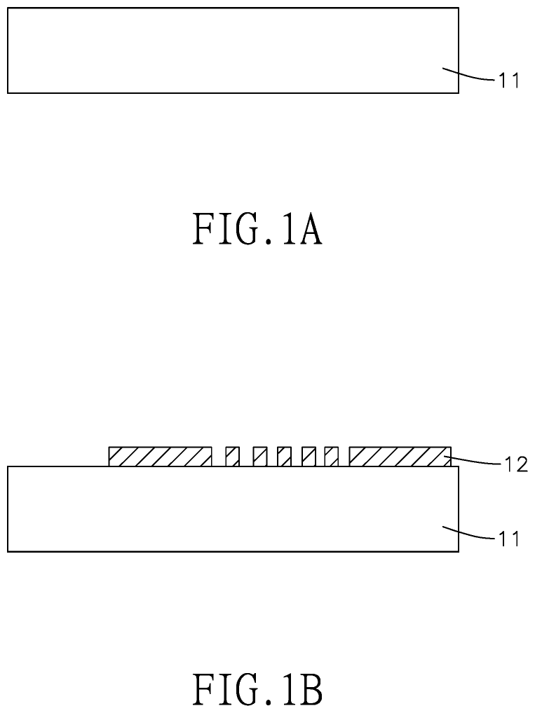

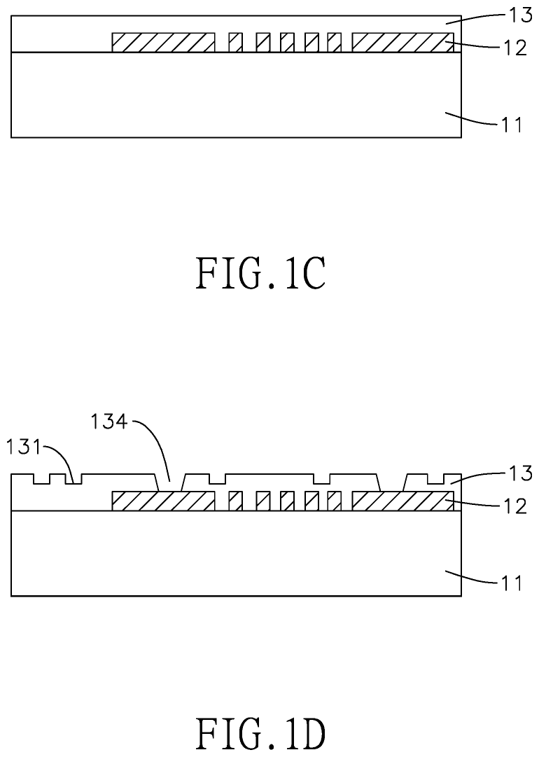

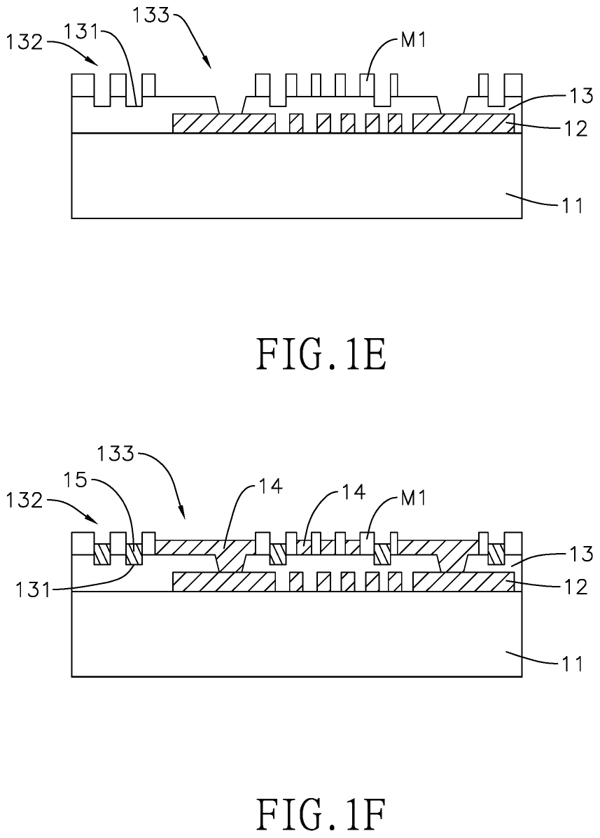

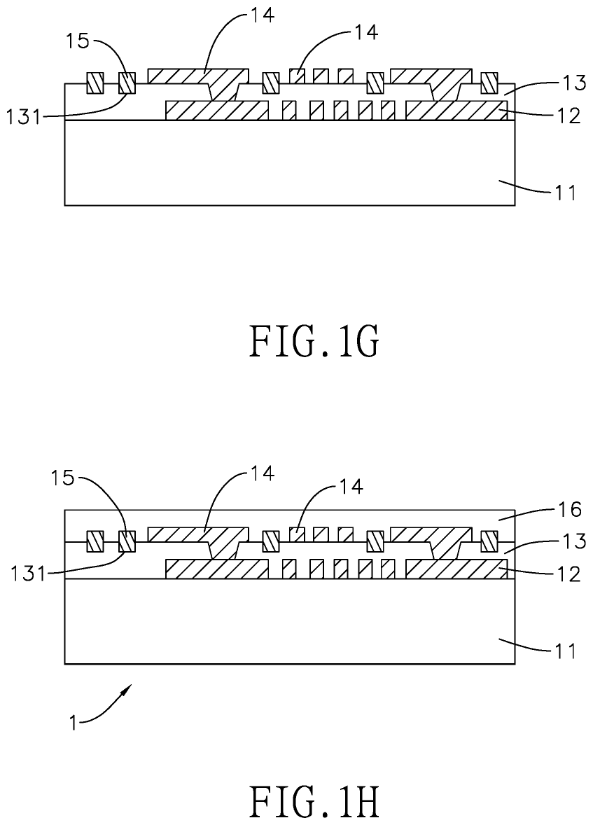

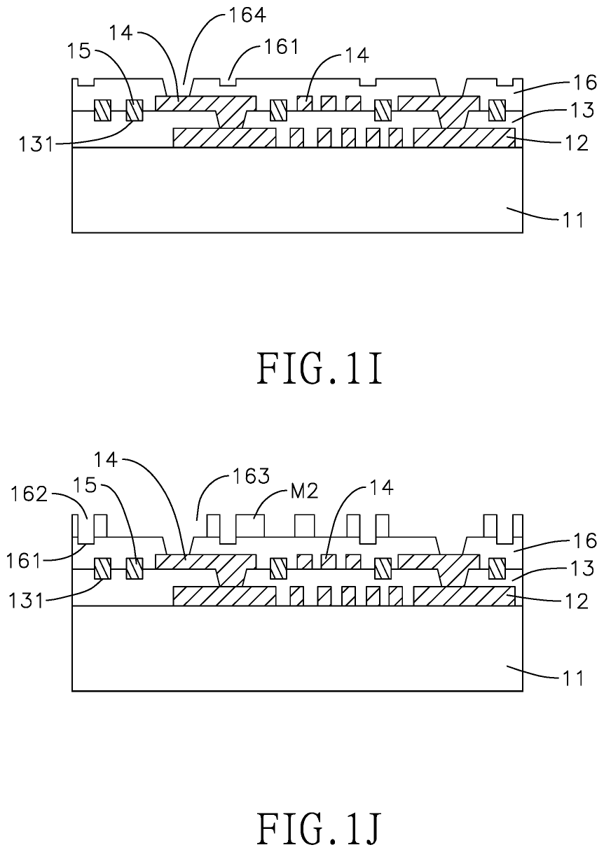

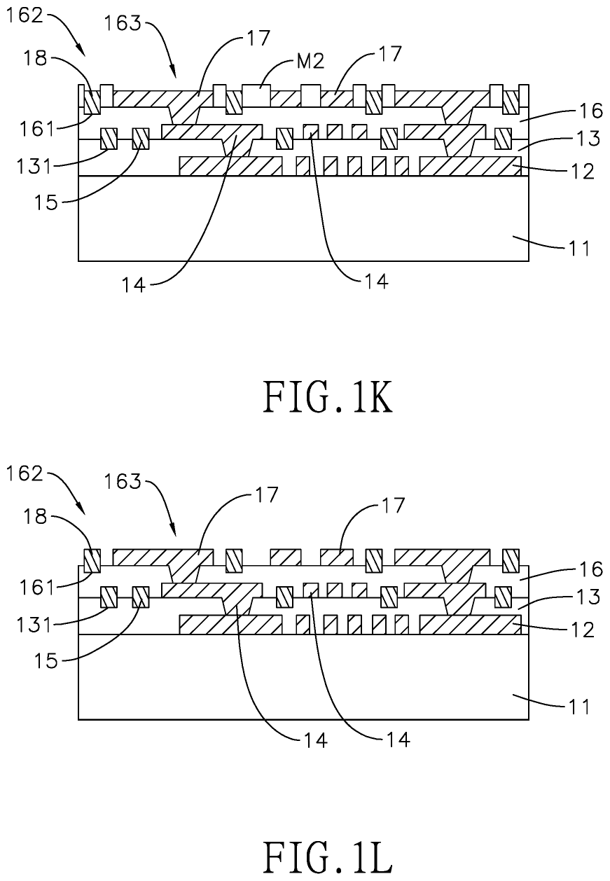

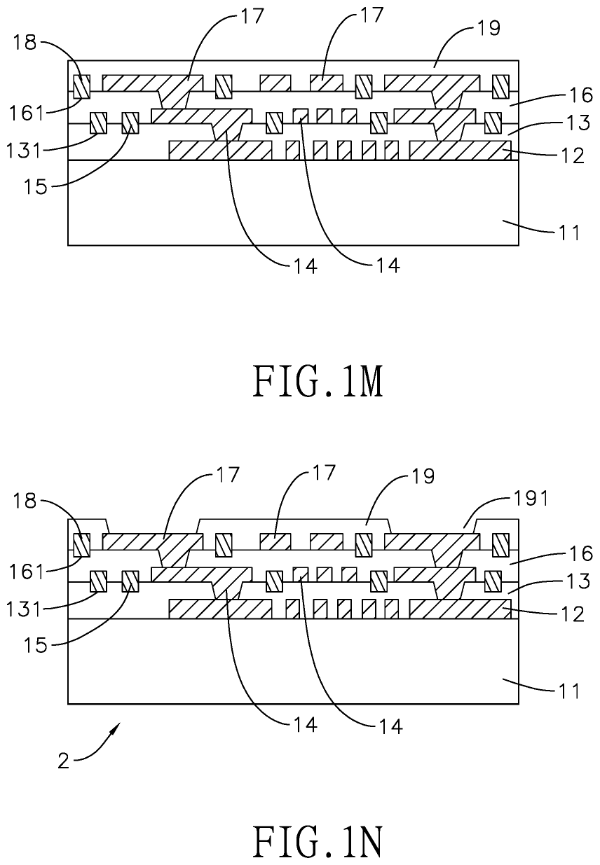

Refer to FIG. 1A to FIG. 1N. FIG. 1A to FIG. 1N are the schematic flowchart of the manufacture method of a circuit board enhancing structure of the present invention. The manufacture method of a circuit board enhancing structure includes the following steps: in the step S11, providing a substrate 11 as shown in FIG. 1A; in the step S12, forming a first circuit 12 on the substrate 11 as shown in FIG. 1B; in the step S13, forming a first dielectric layer 13 on the substrate 11 and encapsulating the first circuit 12 as shown in FIG. 1C; in the step S14, forming at least one first opening 131 on the surface of the first dielectric layer 13 as shown in FIG. 1D; in the step S15, according to a position of the at least one first opening 131 on the surface of the first dielectric layer 13 and a predetermined position of the second circuit 14 on the surface of the first dielectric layer 13, forming the first pattern photoresist layer M1 on the surface of the first dielectric layer 13, to divide the surface of the first dielectric layer 13 as the first structure enhancement region 132 and the second circuit region 133 by the first pattern photoresist layer M1, wherein the at least one first opening 131 is disposed in the first structure enhancement region 132, as shown in FIG. 1E; in the step S16, forming the second circuit 14 in the second circuit region 133, and forming the first enhancing structure element 15 in the first opening 131 of the first structure enhancement region 132, wherein the first enhancing structure element 15 protrudes above the first opening 131 as shown in FIG. 1F; in the step S17, removing the first pattern photoresist layer M1 as shown in FIG. 1G; in the step S18, forming the second dielectric layer 16 on the first dielectric layer 13, and encapsulating the second circuit 14 and the first enhancing structure element 15 as shown in FIG. 1H; in the step S19, forming the at least one second opening 161 on the surface of the second dielectric layer 16 as shown in FIG. 1I; in the step S20, according to the position of the at least one second opening 161 on the surface of the second dielectric layer 16 and the predetermined position of the third circuit 17 on the surface of the second dielectric layer 16, forming the second pattern photoresist layer M2 on the surface of the second dielectric layer 16 to divide the surface of the second dielectric layer 16 as the second structure enhancement region 162 and the third circuit region 163 by the second pattern photoresist layer M2, wherein at least one second opening 161 is disposed in the second structure enhancement region 162 as shown in FIG. 1J; in the step S21, forming the third circuit 17 in the third circuit region 163, and forming the at least one second enhancing structure element 18 in the at least one second opening 161 of the second structure enhancement region 162, wherein the second enhancing structure element 18 protrudes from at least one second opening 161 as shown in FIG. 1K; in the step S22, removing the second pattern photoresist layer M2 as shown in FIG. 1L; in the step S23, forming the protective layer 19 on the second dielectric layer 16, encapsulating the second enhancing structure element 18 and the third circuit 17 as shown in FIG. 1M; in the step S24, forming the at least one opening 191 on the protective layer 19 to expose a part of the third circuit 17 as shown in FIG. 1N.

In the above embodiment, the height of the first enhancing structure element 15 is formed by the first pattern photoresist layer M1 so that the height of the first enhancing structure element 15 is larger than the depth of the first opening 131. Hence, the first enhancing structure element 15 is embedded deeply in the first dielectric layer 13 via the first opening 131. Simultaneously, the part of the first enhancing structure element 15 that protrudes from the first opening 131 is encapsulated by the second dielectric layer 16. That is, the height of the first enhancing structure element 15 is under the surface of the second dielectric layer 13, not yet to protrude beyond the surface of the second dielectric layer 13. Accordingly, the first enhancing structure element 15 is utilized to connect the second dielectric layer 16 and the first dielectric layer 13 to enhance the bonding strength of the contact surface between the first dielectric layer 13 and the second dielectric layer 16.

Moreover, the height of the second enhancing structure element 18 is formed by the second pattern photoresist layer M2 so that the height of the second enhancing structure element 18 is larger than the depth of the second opening 161. Hence, the second enhancing structure element 18 is embedded deeply in the second dielectric layer 16 via the second opening 161. Simultaneously, the part of the second enhancing structure element 18 that protrudes from the second opening 161 is encapsulated by the protective layer 19. That is, the height of the second enhancing structure element 18 is under the surface of the protective layer 19, not yet to protrude beyond the surface of the protective layer 19. Accordingly, the second enhancing structure element 18 is utilized to connect the second dielectric layer 16 and the protective layer 19 to enhance the bonding strength of the contact surface between the protective layer 19 and the second dielectric layer 16.

In addition, in the step S14, the step S14 further includes a step of forming the first through hole 134 in the first dielectric layer 13 so that the second circuit 14 is electrically connected to the first circuit 12 via the first through hole 134. In the step S19, the step S19 further includes a step of forming the second through hole 164 in the second dielectric layer 16 so that the third circuit 17 is electrically connected to the second circuit 14 via the second through hole 164.

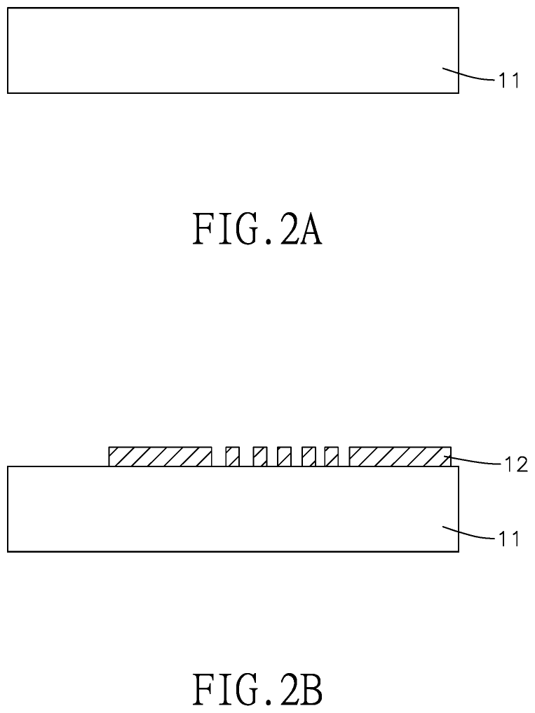

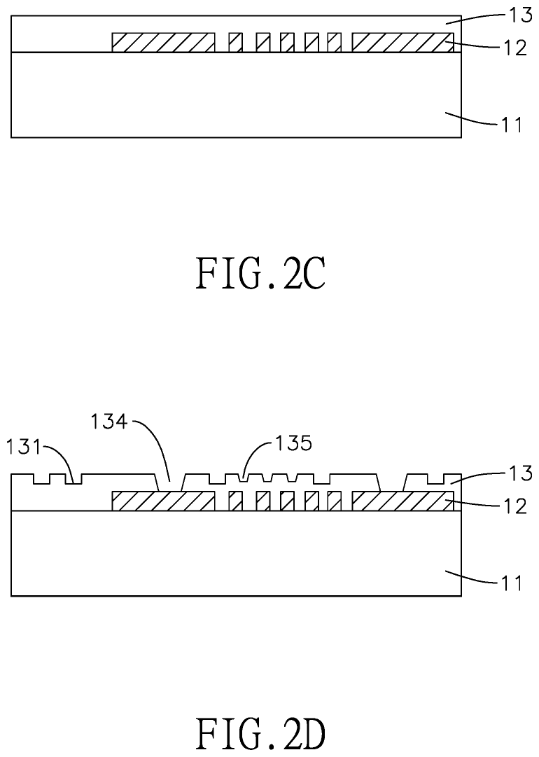

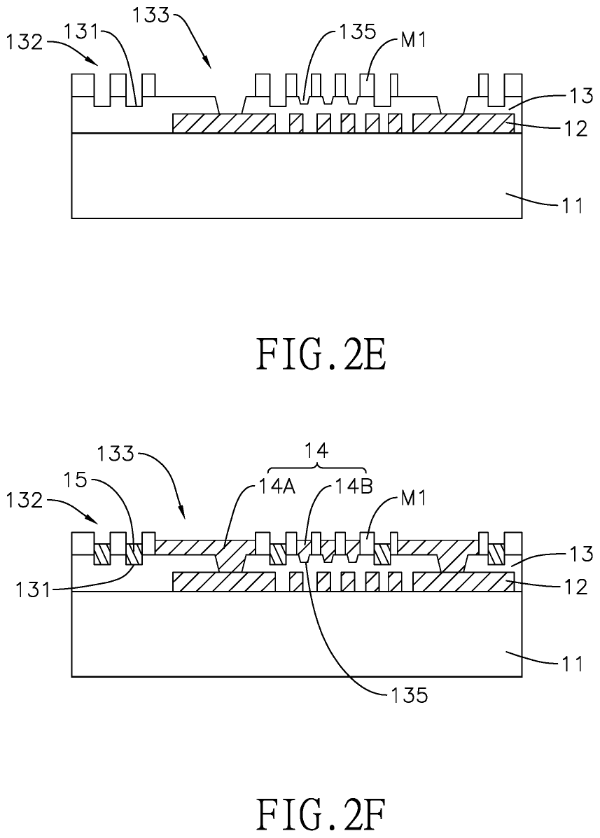

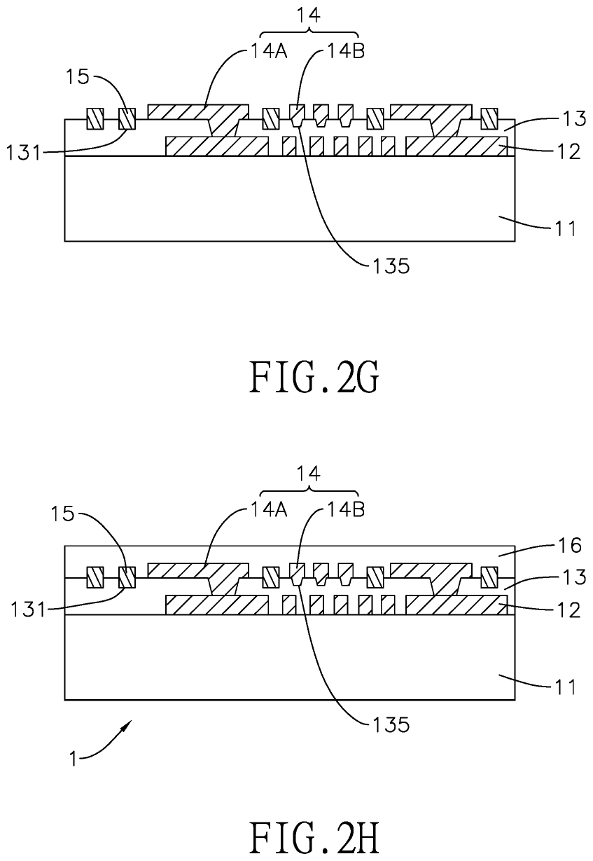

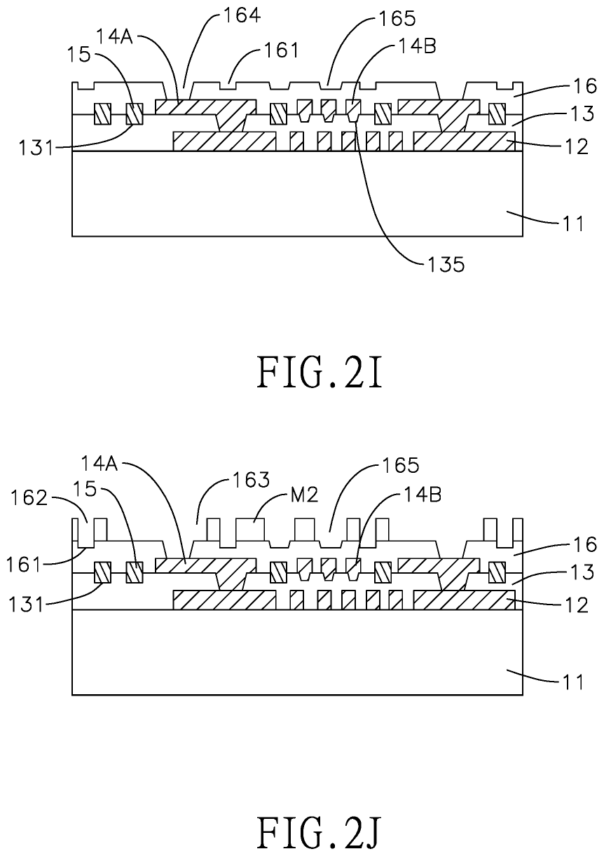

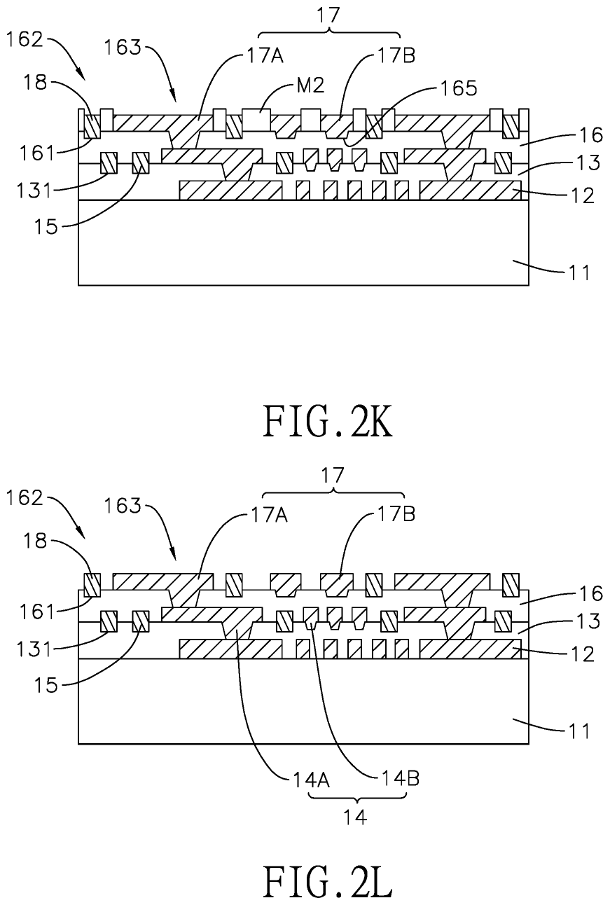

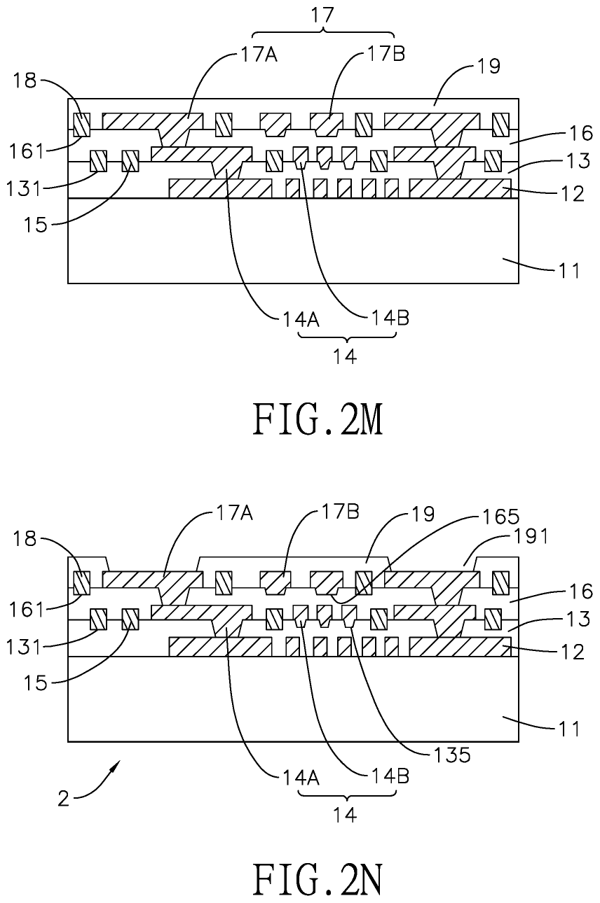

Refer to FIG. 2A to FIG. 2N. FIG. 2A to FIG. 2N are the schematic flowchart of the manufacture method of a circuit board enhancing structure of another embodiment of the present invention. In the embodiment, the manufacture method of a circuit board enhancing structure includes the following steps: in the step S31, providing a substrate 11 as shown in FIG. 2A; in the step S32, forming a first circuit 12 on the substrate 11 as shown in FIG. 2B; in the step S33, forming a first dielectric layer 13 on the substrate 11 and encapsulating the first circuit 12 as shown in FIG. 2C; in the step S34, forming at least one first opening 131 on the surface of the first dielectric layer 13 as shown in FIG. 2D; in the step S35, according to a position of the at least one first opening 131 on the surface of the first dielectric layer 13 and a predetermined position of the second circuit 14 on the surface of the first dielectric layer 13, forming the first pattern photoresist layer M1 on the surface of the first dielectric layer 13, to divide the surface of the first dielectric layer 13 as the first structure enhancement region 132 and the second circuit region 133 by the first pattern photoresist layer M1, wherein the at least one first opening 131 is disposed in the first structure enhancement region 132, as shown in FIG. 2E; in the step S36, forming the second circuit 14 in the second circuit region 133, and forming the first enhancing structure element 15 in the first opening 131 of the first structure enhancement region 132, wherein the first enhancing structure element 15 protrudes from the first opening 131 as shown in FIG. 2F; in the step S37, removing the first pattern photoresist layer M1 as shown in FIG. 2G; in the step S38, forming the second dielectric layer 16 on the first dielectric layer 13, and encapsulating the second circuit 14 and the first enhancing structure element 15 as shown in FIG. 2H; in the step S39, forming the at least one second opening 161 on the surface of the second dielectric layer 16 as shown in FIG. 2I; in the step S40, according to the position of the at least one second opening 161 on the surface of the second dielectric layer 16 and the predetermined position of the third circuit 17 on the surface of the second dielectric layer 16, forming the second pattern photoresist layer M2 on the surface of the second dielectric layer 16 to divide the surface of the second dielectric layer 16 as the second structure enhancement region 162 and the third circuit region 163 by the second pattern photoresist layer M2, wherein at least one second opening 161 is disposed in the second structure enhancement region 162 as shown in FIG. 2J; in the step S41, forming the third circuit 17 in the third circuit region 163, and forming the at least one second enhancing structure element 18 in the at least one second opening 161 of the second structure enhancement region 162, wherein the second enhancing structure element 18 protrudes from the at least one second opening 161 as shown in FIG. 2K; in the step S42, removing the second pattern photoresist layer M2 as shown in FIG. 2L; in the step S43, forming the protective layer 19 on the second dielectric layer 16, and encapsulating the second enhancing structure element 18 and the third circuit 17 as shown in FIG. 2M; in the step S44, forming the at least one opening 191 on the protective layer 19 to expose a part of the third circuit 17 as shown in FIG. 2N.

In the embodiment, the first enhancing structure element 15 is formed by the first pattern photoresist layer M1 so that the height of the first enhancing structure element 15 is larger than the depth of the first opening 131. Hence, the first enhancing structure element 15 is embedded deeply in the first dielectric layer 13 via the first opening 131. Simultaneously, the part of the first enhancing structure element 15 that protrudes from the first opening 131 is encapsulated by the second dielectric layer 16. That is, the height of the first enhancing structure element 15 is under the surface of the second dielectric layer 16, not yet to protrude beyond the surface of the second dielectric layer 16. Accordingly, the first enhancing structure element 15 is utilized to connect the second dielectric layer 16 and the first dielectric layer 13 to enhance the bonding strength of the contact surface between the first dielectric layer 13 and the second dielectric layer 16.

In the embodiment, the second enhancing structure element 18 is formed by the second pattern photoresist layer M2 so that the height of the second enhancing structure element 18 is larger than the depth of the second opening 161. Hence, the second enhancing structure element 18 is embedded deeply in the second dielectric layer 16 via the second opening 161. Simultaneously, the part of the second enhancing structure element 18 that protrudes from the second opening 161 is encapsulated by the protective layer 19. That is, the height of the second enhancing structure element 18 is under the surface of the protective layer 19, not yet to protrude beyond the surface of the protective layer 19. Accordingly, the second enhancing structure element 18 is utilized to connect the second dielectric layer 16 and the protective layer 19 to enhance the bonding strength of the contact surface between the protective layer 19 and the second dielectric layer 16.

In addition, in the embodiment, the circuit board enhancing structure 2 enhances the bonding strength of the contact surface between the first dielectric layer 13 and the second dielectric layer 16, and enhances the bonding strength of the contact surface between the second dielectric layer 16 and the protective layer 19 by the aforementioned first enhancing structure element 15 and the second enhancing structure element 18. Except the first enhancing structure element 15 and the second enhancing structure element 18, the circuit board enhancing structure 2 further modifies the structure of the second circuit 14, having the function for signal connections per se, formed in the second circuit region 133 and the third circuit 17, having the function for signal connections per se, formed in the third circuit region 163 to enhance the bonding strength of the contact surface between the first dielectric layer 13 and the second dielectric layer 16 and to enhance the bonding strength of the contact surface between the second dielectric layer 16 and the protective layer 19. In details, as shown in FIG. 2D, the step S34 further includes a step of forming the first trench 135 on the surface of the first dielectric layer 13. In addition, as shown in FIG. 2I, the step S39 further includes a step of forming the second trench 165 on the surface of the second dielectric layer 16. In the embodiment of the present invention, the first trench 135 and the second trench 165 each have a structure with a wide top and a narrow bottom, including a cone structure. In addition, the position of the first trench 135 and the second trench 165 are disposed according to the predetermined position of the second circuit 14B on the surface of the first dielectric layer 13 and the predetermined position of the third circuit 17B on the surface of the second dielectric layer 16.

As mentioned above, in FIG. 2F, the step S36 further includes a step of forming the second circuit 14B in the at least one first trench 135. In FIG. 2K, the step S41 further includes a step of forming the third circuit 17B in the at least one second trench 165.

As mentioned above, the second circuit 14B is formed by the first pattern photoresist layer M1 so that the height of the second circuit 14B formed in the first trench 135 is larger than the depth of the first trench 135. Hence, the second circuit 14B is embedded deeply in the first dielectric layer 13 via the first trench 135. Simultaneously, the part of the second circuit 14B that protrudes above the first trench 135 is encapsulated by the second dielectric layer 16. That is, the height of the second circuit 14B is under the surface of the second dielectric layer 13, not yet to protrude beyond the surface of the second dielectric layer 13. Accordingly, the second circuit 14B is utilized to connect the second dielectric layer 16 and the first dielectric layer 13 to enhance the bonding strength of the contact surface between the first dielectric layer 13 and the second dielectric layer 16.

Similarly, the third circuit 17B is formed by the second pattern photoresist layer M2 so that the height of the third circuit 17B formed in the second trench 165 is larger than the depth of the second trench 165. Hence, the third circuit 17B is embedded deeply in the second dielectric layer 16 via the second trench 165. Simultaneously, the part of the third circuit 17B that protrudes from the second trench 165 is encapsulated by the protective layer 19. That is, the height of the third circuit 17B is under the surface of the protective layer 19, not yet to protrude beyond the surface of the protective layer 19. Accordingly, the third circuit 17B is utilized to connect the second dielectric layer 16 and the protective layer 19 to enhance the bonding strength of the contact surface between the protective layer 19 and the second dielectric layer 16.

In addition, in FIG. 2D, the step S34 further includes a step of forming the first through hole 134 in the first dielectric layer 13 so that the second circuit 14 is divided to the second circuit 14A formed in the first through hole 134 and the second circuit 14B formed in the first trench 135, as shown in FIG. 2F. The second circuit 14A formed in the first through hole 134 is electrically connected to the first circuit 12 via the first through hole 134 and the second circuit 14B formed in the first trench 135 via the first trench 135, thereby enhancing the bonding strength of the contact surface between the first dielectric layer 13 and the second dielectric layer 16. Besides, the figures in the present invention demonstrate the cross sectional views; in fact, the second circuit 14B formed in the first trench 135 is electrically connected to the second circuit 14A formed in the first through hole 134 to transmit signals.

Moreover, in FIG. 2I, the step S39 further includes a step of forming the second through hole 164 in the second dielectric layer 16 so that the third circuit 17 is divided to the third circuit 17A formed in the second through hole 164 and the third circuit 17B formed in the second trench 165, as shown in FIG. 2K. The third circuit 17A formed in the second through hole 164 is electrically connected to the second circuit 14A via the second through hole 164 and the third circuit 17B formed in the second trench 165 via the second trench 165, thereby enhancing the bonding strength of the contact surface between the protective layer 19 and the second dielectric layer 16. Besides, the figures in the present invention demonstrate the cross sectional views, in fact, the third circuit 17B formed in the second trench 165 is electrically connected to the third circuit 17A formed in the second through hole 164 to transmit signals.

In the step S14, the step S19, the step S34 and the step S39, the first opening 131, the second opening 161, the first trench 135, and the second trench 165 are formed by an etching process or an exposure developing process.

In the step S23 and the step S43, the protective layer 19 is a low moisture absorption material, including a solder mask, teflon, and so on. In addition, the part of the third circuit 17 exposed and not covered by the protective layer 19 is used as an external connection point.

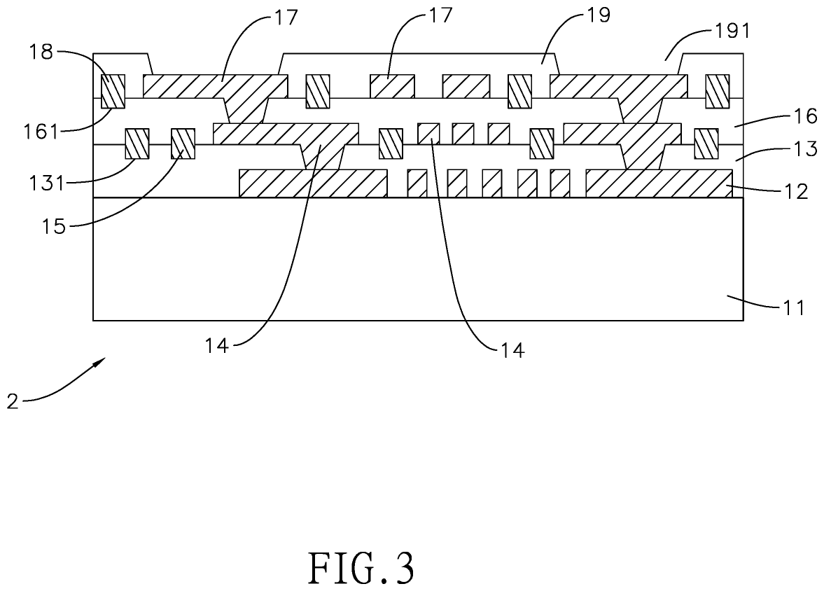

Refer to FIG. 3. FIG. 3 is the cross sectional view of the circuit board enhancing structure manufactured by the manufacture method of a circuit board enhancing structure according to FIG. 1A to FIG. 1N. The circuit board enhancing structure 1 includes a substrate 11, a first circuit 12, a first dielectric layer 13, at least one first enhancing structure element 15, a second circuit 14 and a second dielectric layer 16. The first circuit 12 is disposed on the substrate 11. The first dielectric layer 13 is disposed on the substrate 11 and encapsulates the first circuit 12. The surface of the first dielectric layer 13 has first openings 131. The second circuit 14 is disposed on the surface of the first dielectric layer 13. The at least one first enhancing structure element 15 is disposed in the at least one first opening 131 of the first dielectric layer 13, and protrudes from the at least one first opening 131. The second circuit 14 is disposed on the surface of the first dielectric layer 13. The second dielectric layer 16 is disposed on the first dielectric layer 13 and encapsulates the second circuit 14 and the at least one first enhancing structure element 15.

In the above structures, the height of the first enhancing structure element 15 is larger than the depth of the first opening 131. Hence, the first enhancing structure element 15 is embedded deeply in the first dielectric layer 13 via the first opening 131. Simultaneously, the part of the first enhancing structure element 15 that protrudes from the first opening 131 is encapsulated by the second dielectric layer 16. That is, the height of the first enhancing structure element 15 is under the surface of the second dielectric layer 16, not yet to protrude beyond the surface of the second dielectric layer 16. Accordingly, the first enhancing structure element 15 is utilized to connect the second dielectric layer 16 and the first dielectric layer 13 to enhance the bonding strength of the contact surface between the first dielectric layer 13 and the second dielectric layer 16. In addition, since the first enhancing structure element 15 is disposed in the first opening 131, the position and the width of the first opening 131 are not limited to the surface of the first dielectric layer 13. Alternatively, the first opening 131 can be disposed in the region excluding the circuit region and the interval between the first opening 131 and the region excluding the circuit region is not less than the interval of the minimum process. Moreover, the first structure enhancement region 132 includes the regions formed by the first pattern photoresist layer M1 encapsulating each first opening 131.

Similarly, in the above structures, the height of the second enhancing structure element 18 is larger than the depth of the second opening 161. Hence, the second enhancing structure element 18 is embedded deeply in the second dielectric layer 16 via the second opening 161. Simultaneously, the part of the second enhancing structure element 18 that protrudes from the second opening 161 is encapsulated by the protective layer 19. That is, the height of the second enhancing structure element 18 is under the surface of the protective layer 19, not yet to protrude beyond the surface of the protective layer 19. Accordingly, the second enhancing structure element 18 is utilized to connect the second dielectric layer 16 and the protective layer 19 to enhance the bonding strength of the contact surface between the protective layer 19 and the second dielectric layer 16. In addition, since the second enhancing structure element 18 is disposed in the second opening 161, the position and the width of the second opening 161 are not limited to the surface of the second dielectric layer 16. Alternatively, the second opening 161 can be disposed in the region excluding the circuit region and the interval between the second opening 161 and the region excluding the circuit region is not less than the interval of the minimum process. Moreover, the second structure enhancement region 162 includes the regions formed by the second pattern photoresist layer M2 encapsulating each second opening 161.

In the embodiment, in terms of shapes, the at least one first opening 131 and the at least one second opening 161 include a cylindrical blind hole so that the first enhancing structure element 15 disposed in the first opening 131 and the second enhancing structure element 18 disposed in the second opening 161 can respectively enhance the bonding strength of the contact surface between the first dielectric layer 13 and the second dielectric layer 16 and the bonding strength of the contact surface between the second dielectric layer 16 and the protective layer 19.

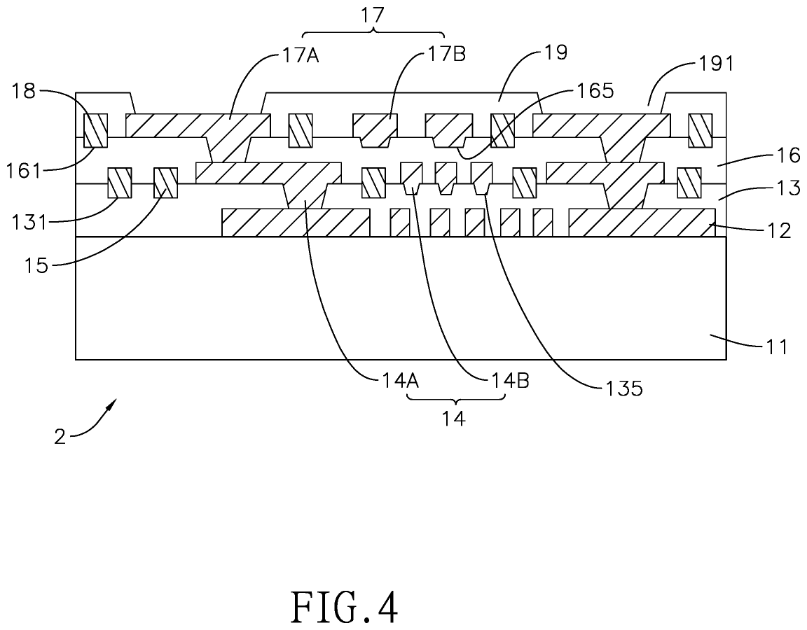

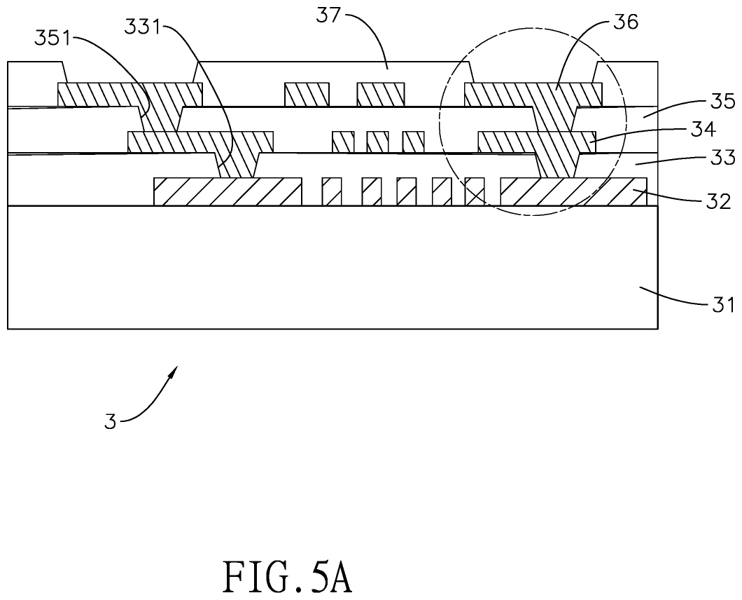

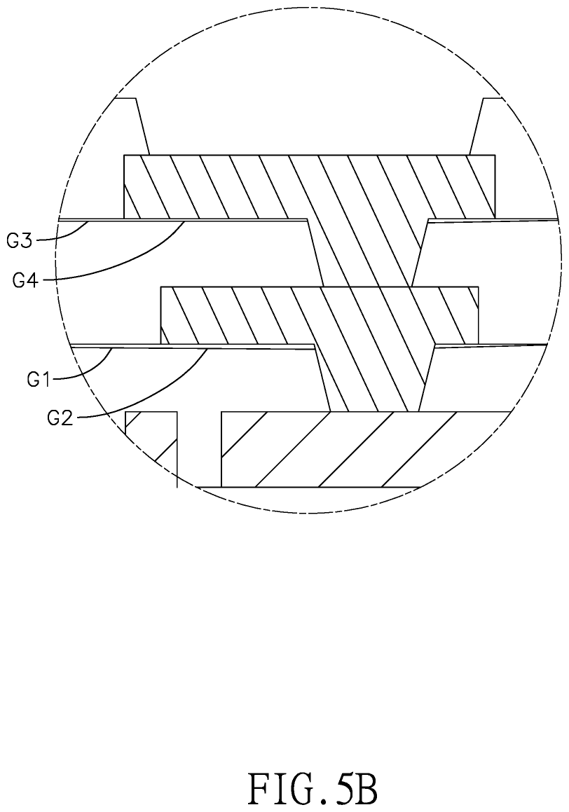

Refer to FIG. 4. FIG. 4 is the cross sectional view of the circuit board enhancing structure manufactured by the manufacture method of a circuit board enhancing structure according to FIG. 2A to FIG. 2N. The circuit board enhancing structure 1 includes a substrate 11, a first circuit 12, a first dielectric layer 13, at least one first enhancing structure element 15, a second circuit 14 and a second dielectric layer 16. The first circuit 12 is disposed on the substrate 11. The first dielectric layer 13 is disposed on the substrate 11 and encapsulates the first circuit 12. The surface of the first dielectric layer 13 has first openings 131. The second circuit 14 is disposed on the surface of the first dielectric layer 13. The at least one first enhancing structure element 15 is disposed in the at least one first opening 131 of the first dielectric layer 13, and protrudes from the at least one first opening 131. The second circuit 14 is disposed on the surface of the first dielectric layer 13. The second dielectric layer 16 is disposed on the first dielectric layer 13 and encapsulates the second circuit 14 and the at least one first enhancing structure element 15.

In the above structures, the height of the first enhancing structure element 15 is larger than the depth of the first opening 131. Hence, the first enhancing structure element 15 is embedded deeply in the first dielectric layer 13 via the first opening 131. Simultaneously, the part of the first enhancing structure element 15 that protrudes from the first opening 131 is encapsulated by the second dielectric layer 16. That is, the height of the first enhancing structure element 15 is under the surface of the second dielectric layer 16, not yet to protrude beyond the surface of the second dielectric layer 16. Accordingly, the first enhancing structure element 15 is utilized to connect the second dielectric layer 16 and the first dielectric layer 13 to enhance the bonding strength of the contact surface between the first dielectric layer 13 and the second dielectric layer 16. In addition, since the first enhancing structure element 15 is disposed in the first opening 131, the position and the width of the first opening 131 are not limited to the surface of the first dielectric layer 13. Alternatively, the first opening 131 can be disposed in the region excluding the circuit region and the interval between the first opening 131 and the region excluding the circuit region is not less than the interval of the minimum process. Moreover, the first structure enhancement region 132 includes the regions formed by the first pattern photoresist layer M1 encapsulating each first opening 131.

Similarly, in the above structures, the height of the second enhancing structure element 18 is higher than the depth of the second opening 161. Hence, the second enhancing structure element 18 is embedded deeply in the second dielectric layer 16 via the second opening 161. Simultaneously, the part of the second enhancing structure element 18 that protrudes from the second opening 161 is encapsulated by the protective layer 19. That is, the height of the second enhancing structure element 18 is under the surface of the protective layer 19, not yet to protrude beyond the surface of the protective layer 19. Accordingly, the second enhancing structure element 18 is utilized to connect the second dielectric layer 16 and the protective layer 19 to enhance the bonding strength of the contact surface between the protective layer 19 and the second dielectric layer 16. In addition, since the second enhancing structure element 18 is disposed in the second opening 161, the position and the width of the second opening 161 are not limited to the surface of the second dielectric layer 16. Alternatively, the second opening 161 can be disposed in the region excluding the circuit region and the interval between the second opening 161 and the region excluding the circuit region is not less than the interval of the minimum process. Moreover, the second structure enhancement region 162 includes the regions formed by the second pattern photoresist layer M2 encapsulating each second opening 161.

In the embodiment, in terms of shape, the at least one first opening 131 and the at least one second opening 161 include a cylindrical blind hole so that the first enhancing structure element 15 disposed in the first opening 131 and the second enhancing structure element 18 disposed in the second opening 161 can respectively enhance the bonding strength of the contact surface between the first dielectric layer 13 and the second dielectric layer 16 and the bonding strength of the contact surface between the second dielectric layer 16 and the protective layer 19.

In the embodiment, the circuit board enhancing structure 2 further includes at least one first trench 135 and at least one second trench 165. The at least one first trench 135 and the at least one second trench 165, in terms of shape, include a conical blind hole with a wide top and a narrow bottom so that the second circuit 14B disposed in the first trench 135 and the third circuit 17B disposed in the second trench 165 can respectively enhance the bonding strength of the contact surface between the first dielectric layer 13 and the second dielectric layer 16 and the bonding strength of the contact surface between the second dielectric layer 16 and the protective layer 19.

In the embodiment, the circuit board enhancing structure 2 further includes a first through hole 134 and a second through hole 164. The first through hole 134 is disposed in the first dielectric layer 13 so that the second circuit 14A is electrically connected to the first circuit 12 via the first through hole 133. The second through hole 164 is disposed in the second dielectric layer 16 so that the third circuit 17A is electrically connected to the second circuit 14A via the second through hole 164.

In the embodiment of the present invention, the first circuit 12, the second circuit 14A, the second circuit 14B, the third circuit 17A, the third circuit 17B, the first enhancing structure element 15 and the second enhancing structure element 18 use the same materials, such as copper and other conductive metal materials so as to reduce the steps of the manufacture method of a circuit board enhancing structure.

To summarize, the circuit board enhancing structure and the manufacture method thereof of the present invention utilize the enhancing structure elements to enhance the vertical bonding strength of the contact surface between the various processes. For instance, the invention enhances the bonding strength between the various dielectric layers and enhances the bonding strength between the dielectric layer and the protective layer to overcome the problems of the prior art. In addition, the enhancing structure elements are inserted into to the interior of the dielectric layer to decrease and release the thermal stress in the dielectric layer, to reinforce the strength of the whole structure of the circuit board and to improve the homogeneity of the electroplating process. In this way, the circuit board enhancing structure and the manufacture method thereof of the present invention can further be applied to the layered structure with a low thermal expansion coefficient and the structure of the 5G product with a low roughness surface.

Even though numerous characteristics and advantages of the present invention have been set forth in the foregoing description, together with details of the structure and function of the invention, the disclosure is illustrative only. Changes may be made in detail, especially in matters of shape, size, and arrangement of parts within the principles of the invention to the full extent indicated by the broad general meaning of the terms in which the appended claims are expressed.

What is claimed is:

1. A manufacture method of a circuit board enhancing structure,
comprising the following steps:
providing a substrate;
forming a first circuit on the substrate;
forming a first dielectric layer on the substrate, and encapsulating the first circuit;
forming at least one first opening;
forming a first pattern photoresist layer on a surface of the first dielectric layer to divide the surface of the first dielectric layer as a first structure enhancement region and a second circuit region by the first pattern photoresist layer, wherein the at least one first opening is disposed in the first structure enhancement region;
forming a second circuit in the second circuit region, and forming at least one first enhancing structure element in the at least one first opening of the first structure enhancement region, protruding above the at least one first opening;
removing the first pattern photoresist layer; and
forming a second dielectric layer on the first dielectric layer, and encapsulating the second circuit and the at least one first enhancing structure element.

2. The manufacture method of a circuit board enhancing structure as claimed in claim 1, further comprising the following steps:
forming at least one second opening on a surface of the second dielectric layer;
forming a second pattern photoresist layer on the surface of the second dielectric layer, to divide the surface of the second dielectric layer as a second structure enhancement region and a third circuit region by the second pattern photoresist layer, wherein the at least one second opening is disposed in the second structure enhancement region;
forming a third circuit in the third circuit region, and forming at least one second enhancing structure element in the at least one second opening of the second structure enhancement region, protruding from the at least one second opening;
removing the second pattern photoresist layer;
forming a protective layer on the surface of the second dielectric layer, and encapsulating the second enhancing structure element and the third circuit; and
forming at least one opening on the protective layer to expose a part of the third circuit.

3. The manufacture method of a circuit board enhancing structure as claimed in claim 2, wherein the step of forming the at least one first opening in the surface of the first dielectric layer further comprises a step of forming at least one first trench with a wide top and a narrow bottom on the surface of the first dielectric layer.

4. The manufacture method of a circuit board enhancing structure as claimed in claim 3, wherein the step of forming the second circuit in the second circuit region further comprises a step of forming the second circuit in the at least one first trench, protruding from the at least one first trench.

5. The manufacture method of a circuit board enhancing structure as claimed in claim 4, wherein the step of forming the at least one second opening in the surface of the second dielectric layer further comprises a step of forming at least one second trench with a wide top and a narrow bottom on the surface of the second dielectric layer.

6. The manufacture method of a circuit board enhancing structure as claimed in claim 5, wherein the step of forming the third circuit in the third circuit region further comprises a step of forming the third circuit in the at least one second trench, protruding from the at least one second trench.

7. The manufacture method of a circuit board enhancing structure as claimed in claim 6, wherein the first opening, the second opening, the first trench, and the second trench are formed by an etching process or a exposure developing process.

8. The manufacture method of a circuit board enhancing structure as claimed in claim 6, wherein the step of forming the at least one first opening on the surface of the first dielectric layer further comprises a step of forming a first through hole in the second circuit region of the first dielectric layer, connected to the first circuit and the second circuit.

9. The manufacture method of a circuit board enhancing structure as claimed in claim 8, wherein the step of forming the at least one second opening on the surface of the second dielectric layer further comprises a step of forming a second through hole in the third circuit region of the second dielectric layer, connected to the second circuit and the third circuit.

10. A circuit board enhancing structure, comprising:
a substrate;
a first circuit, disposed on the substrate;
a first dielectric layer, disposed on the substrate, encapsulating the first circuit, and a surface of the first dielectric layer having at least one first opening;
at least one first enhancing structure element, disposed in the at least one first opening on the first dielectric layer, and protruding from the at least one first opening;
a second circuit, disposed on the surface of the first dielectric layer; and
a second dielectric layer, disposed on the first dielectric layer, and encapsulating the second circuit and the at least one first enhancing structure element.

11. The circuit board enhancing structure as claimed in claim 10, wherein a surface of the second dielectric layer has at least one second opening, and the circuit board enhancing structure further comprises:
a third circuit, disposed on the surface of the second dielectric layer;
at least one second enhancing structure element, disposed in the at least one second opening on the second dielectric layer, and protruding from the at least one second opening; and
a protective layer, disposed on the second dielectric layer, exposing one part of the third circuit, and encapsulating the at least one second enhancing structure element and the other part of the third circuit.

12. The circuit board enhancing structure as claimed in claim 11, wherein the first circuit, the second circuit, the third circuit, the at least one first enhancing structure element, and the at least one second enhancing structure element are made of the same materials.

13. The circuit board enhancing structure as claimed in claim 11, wherein the first dielectric layer and the second dielectric layer respectively have at least one first through hole and at least one second through hole, the second circuit is electrically connected to the first circuit via the at least one first through hole, and the third circuit is electrically connected to the second circuit via the at least one second through hole.

14. The circuit board enhancing structure as claimed in claim 13, wherein the surface of the first dielectric layer has at least one first trench, and the second circuit is further disposed on the at least one first trench, protruding from the at least one first trench.

15. The circuit board enhancing structure as claimed in claim 14, wherein the surface of the second dielectric layer has at least one second trench, and the third circuit is further disposed on the at least one second trench, protruding from the at least one second trench.

16. The circuit board enhancing structure as claimed in claim 10, wherein the at least one first opening and the at least one second opening include a cylindrical blind hole.

17. The circuit board enhancing structure as claimed in claim 15, wherein the at least one first trench and the at least one second trench include a conical blind hole.
